(19) United States
(12) Patent Application Publication
(10) Pub. No.: US 2026/0079389 A1
(43) Pub. Date: Mar. 19, 2026

(54) MULTILAYER REFLECTIVE FILM-PROVIDED SUBSTRATE, METHOD FOR PRODUCING MULTILAYER REFLECTIVE FILM-PROVIDED SUBSTRATE, REFLECTIVE MASK BLANK, REFLECTIVE MASK, AND METHOD FOR PRODUCING REFLECTIVE MASK

(71) Applicant: AGC Inc., Tokyo (JP)

(72) Inventors: Ryosuke SEI, Tokyo (JP); Keishi TSUKIYAMA, Tokyo (JP)

(73) Assignee: AGC Inc., Tokyo (JP)

(21) Appl. No.: 19/368,174

(22) Filed: Oct. 24, 2025

Related U.S. Application Data
(63) Continuation of application No. PCT/JP2024/027152, filed on Jul. 30, 2024.

(30) Foreign Application Priority Data
Aug. 16, 2023 (JP) 2023-132506

(51) Int. Cl. G03F 1/24; G03F 7/00

(52) U.S. Cl. CPC G03F 1/24; G03F 7/0005

(57) ABSTRACT

To provide a multilayer reflective film-provided substrate in which the thickness of a diffusion layer in the multilayer reflective film when heated is less likely to change. A multilayer reflective film-provided substrate for reflective mask blank, comprising a substrate, and a multilayer reflective film to reflect EUV light, wherein the multilayer reflective film has a structure such that low refractive index layers and high refractive index layers are alternately stacked; and in a diffraction chart obtained by X-ray diffraction measurement, a crystallite size calculated from a diffraction peak with a maximum intensity attributable to the low refractive index layers is more than 3.1 nm.

### TECHNICAL FIELD

The present invention relates to a multilayer reflective film-provided substrate used for production of a reflective mask blank which is an original plate of a reflective mask used for EUV (Extreme Ultra Violet) exposure during an exposure process in the manufacturing of semiconductors.

The present invention further relates to a reflective mask blank, a reflective mask and a method for producing a reflective mask.

### BACKGROUND ART

Recent years have seen studies of EUV lithography, which uses EUV light with a center wavelength of about 13.5 nm as a light source, for further miniaturization of semiconductor devices.

In EUV exposure, a reflective optical system and a reflective mask are used in view of the characteristics of EUV light.

The reflective mask has a multilayer reflective film provided on a substrate to reflect EUV light and a patterned absorber film provided on the multilayer reflective film to absorb EUV light.

EUV light incident on the reflective mask from an illumination optical system of exposure equipment is reflected in areas (opening areas) where the absorber film is not present and is absorbed in areas (non-opening areas) where the absorber film is present. Consequently, the mask pattern is transferred as a resist pattern onto a wafer through a reductive projection optical system of exposure equipment, and then, the subsequent processing is carried out.

In the multilayer reflective film-provided substrate or the reflective mask blank, the multilayer reflective film may be a multilayer reflective film in which low refractive index layers (for example molybdenum layers) and high refractive index layers (for example silicon layers) are alternately stacked.

As a method of forming such a multilayer reflective film, for example, Patent Document 1 discloses formation of low refractive index layers and high refractive index layers alternately by sputtering method in which the pressure at the time of forming each layer is adjusted.

### PRIOR ART DOCUMENTS

### Patent Documents

Patent Document 1: JP-A-2021-139970

### DISCLOSURE OF INVENTION

### Technical Problem

The multilayer reflective film-provided substrate (reflective mask blank) may sometimes be heated at the time of forming other layers, during mask forming process, etc.

When the multilayer reflective film-provided substrate (reflective mask blank) is heated, between adjacent low refractive index layer and high refractive index layer in contact with each other in the multilayer reflective film, elements of materials constituting the respective layers may diffuse into each other to change the thickness of a resulting diffusion layer. If the thickness of the diffusion layer changes, reflection properties of the multilayer reflective film may change, and thus it has been desired to suppress the change of the thickness of the diffusion layer by heating.

The present inventors have studied the technique disclosed in Patent Document 1 and found that the thickness of the diffusion layer may change when the multilayer reflective film-provided substrate is heated, and the change should further be suppressed.

The present invention has been made in view of the above-mentioned problems. It is an object of the present invention to provide a multilayer reflective film-provided substrate such that the thickness of the diffusion layer present in the multilayer reflective film is less likely to change when heated.

It is also an object of the present invention to provide a reflective mask blank, a reflective mask, and a method for producing a reflective mask.

### Solution to Problem

As a result of intensive studies made on the above-mentioned problems, the present inventors have found that it is important to adjust the crystallite size of the low refractive index layers in the multilayer reflective film, and then, have accomplished the present invention.

In other words, the present inventors have found the above objects are achieved by the following constitution.

[1] A multilayer reflective film-provided substrate for reflective mask blank, comprising:
a substrate, and
a multilayer reflective film to reflect EUV light,
wherein
the multilayer reflective film has a structure such that low refractive index layers and high refractive index layers are alternately stacked, and
in a diffraction chart obtained by X-ray diffraction measurement, a crystallite size calculated from a diffraction peak with the maximum intensity attributable to the low refractive index layers is more than 3.1 nm.

[2] The multilayer reflective film-provided substrate according to [1], wherein
the low refractive index layers contain molybdenum, and
the high refractive index layers contain silicon.

[3] The multilayer reflective film-provided substrate according to [2], wherein in X-ray fluorescence analysis, a ratio of a detection intensity of ArKα ray to a detection intensity of MoLα ray is 0.0010 or less.

[4] The multilayer reflective film-provided substrate according to [2] or [3], wherein in X-ray fluorescence analysis, a ratio of a detection intensity of AlKα ray to a detection intensity of MoLα ray is 0.0030 or less.

[5] The multilayer reflective film-provided substrate according to any one of [2] to [4], wherein in rocking curve measurement with respect to a peak attributable to 110 reflection of molybdenum in the low refractive index layers, a half-width is 11.8° or more.

[6] The multilayer reflective film-provided substrate according to any one of [1] to [5], wherein, to a total thickness of a pair of one low refractive index layer and one high refractive index layer, a ratio of a thickness of the low refractive index layer is 0.40 or more.

[7] A method for producing the multilayer reflective film-provided substrate as defined in any one of [1] to [6], which comprises:
forming the low refractive index layers and the high refractive index layers by magnetron sputtering method.

[8] A reflective mask blank, comprising, in order:
a substrate,
a multilayer reflective film to reflect EUV light, and
an absorber film,
wherein
the multilayer reflective film has a structure such that low refractive index layers and high refractive index layers are alternately stacked, and
in X-ray diffraction measurement, a crystallite size calculated from a diffraction peak with a maximum intensity attributable to the low refractive index layers is more than 3.1 nm.

[9] The reflective mask blank according to [8], wherein
the low refractive index layers contain molybdenum, and
the high refractive index layers contain silicon.

[10] The reflective mask blank according to [9], wherein in X-ray fluorescence analysis, a ratio of a detection intensity of ArKα ray to a detection intensity of MoLα ray is 0.0010 or less.

[11] The reflective mask blank according to [9] of [10], wherein in X-ray fluorescence analysis, a ratio of a detection intensity of AlKα ray to a detection intensity of MoLα ray is 0.0030 or less.

[12] The reflective mask blank according to any one of [9] to [11], wherein in rocking curve measurement with respect to a peak attributable to 110 reflection of molybdenum in the low refractive index layers, a half-width is 11.8° or more.

[13] The reflective mask blank according to any one of [8] to [12], wherein, to a total thickness of a pair of one low refractive index layer and one high refractive index layer, a ratio of a thickness of the low refractive index layer is 0.40 or more.

[14] A reflective mask having a phase shift film pattern formed by patterning the absorber film of the reflective mask blank as defined in any one of [8] to [13].

[15] A method for producing a reflective mask, which comprises a step of patterning the absorber film in the reflective mask blank as defined in any one of [8] to [13].

### Advantageous Effects of Invention

The present invention provides a multilayer reflective film-provided substrate such that the thickness of a diffusion layer present in the multilayer reflective film is less likely to change when heated.

The present invention also provides a reflective mask blank, a reflective mask, and a method for producing a reflective mask.

### BRIEF DESCRIPTION OF DRAWINGS

FIG. 1 is a schematic view illustrating an example of an embodiment of the multilayer reflective film-provided substrate of the present invention.

FIG. 2 is a schematic view illustrating an example of an embodiment of the reflective mask blank of the present invention.

FIG. 3A is a schematic illustrating an example of an embodiment of a resist pattern formed on a reflective mask blank.

FIG. 3B is a schematic illustrating an example of an embodiment of a laminate with an absorber film pattern.

FIG. 3C is a schematic illustrating an example of an embodiment of a resist pattern formed on a laminate.

FIG. 3D is a schematic illustrating an example of an embodiment of a reflective mask.

### DESCRIPTION OF EMBODIMENTS

Hereinafter, the present invention will be described in detail below.

It should be understood that, although the following description of the features of the present invention will be made based on typical embodiments of the present invention, these typical embodiments are not intended to limit the present invention thereto.

The following expressions used in the present specification have the following meanings.

In the present specification, a numerical range expressed using “to” means a range including numerical values described before and after “to” as lower and upper limits.

In the present specification, elements such as boron, carbon, nitrogen, oxygen, silicon, titanium, chromium, zirconium, niobium, molybdenum, ruthenium, rhodium, palladium, tantalum, rhenium, iridium and platinum etc. may be respectively expressed by their corresponding chemical symbols (B, C, N, O, Si, Ti, Cr, Zr, Nb, Mo, Ru, Rh, Pd, Ta, Re, Ir and Pt etc.).

### <Multilayer Reflective Film-Provided Substrate>

The multilayer reflective film-provided substrate of the present invention is a multilayer reflective film-provided substrate for reflective mask blank, comprising a substrate, and a multilayer reflective film to reflect EUV light. In the multilayer reflective film-provided substrate of the present invention, the multilayer reflective film has a structure such that low refractive index layers and high refractive index layers are alternately stacked; and in a diffraction chart obtained by X-ray diffraction measurement, a crystallite size calculated from a diffraction peak with the maximum intensity attributable to the low refractive index layers is more than 3.1 nm.

The multilayer reflective film-provided substrate may have a back-side conductive film as described in the section on the reflective mask blank.

The multilayer reflective film-provided substrate of the present invention will be described with reference to Drawings.

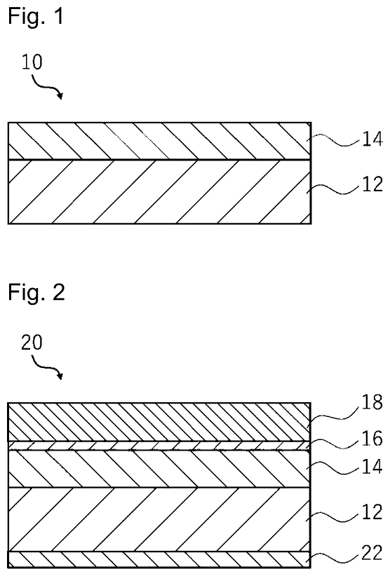

FIG. 1 is a cross-sectional view illustrating an example of an embodiment of the multilayer reflective film-provided substrate of the present invention. A multilayer reflective film-provided substrate 10 shown in FIG. 1 has a substrate 12 and a multilayer reflective film 14.

The multilayer reflective film 14 has a structure such that low refractive index layers and high refractive index layers are alternately stacked, and in a diffraction chart obtained by X-ray diffraction measurement, a crystallite size calculated from a diffraction peak with the maximum intensity attributable to the low refractive index layers is more than 3.1 nm.

The mechanism by which the thickness of a diffusion layer present in the multilayer reflective film is less likely to change when heated, in the multilayer reflective film-provided substrate of the present invention, is not entirely clear, but is assumed to be as follows by the present inventors.

In the multilayer reflective film-provided substrate of the present invention, it is considered that since the crystallite size calculated from a diffraction peak with the maximum intensity attributable to the low refractive index layers is more than 3.1 nm, the crystal particle size tends to be large, the interfacial energy tends to be small, and thus the low refractive index layers are thermally stable. Thus, when the multilayer reflective film-provided substrate is heated, elements of the materials constituting each low refractive index layer are less likely to diffuse and as a result, the thickness of the diffusion layer is less likely to change.

In the following, the configuration of the multilayer reflective film-provided substrate of the present invention will be described.

### [Substrate]

It is preferable that the substrate of the multilayer reflective film-provided substrate the present invention has a low thermal expansion coefficient. When the thermal expansion coefficient of the substrate is low, it is possible to suppress a distortion in the absorber film pattern due to heat generated during EUV exposure.

The thermal expansion coefficient of the substrate at 20° C. is preferably 0±1.0×10⁻⁷/° C., more preferably 0±0.3×10⁻⁷/° C.

As a material having a low thermal expansion coefficient, SiO₂—TiO₂ glass may be mentioned. Substrates of crystallized glass with a β-quartz solid solution precipitated therein, quartz glass, metallurgical grade silicon, metal, and the like are also usable.

The SiO₂—TiO₂ glass is preferably quartz glass having a SiO₂ content of 90 to 95 mass % and a TiO₂ content of 5 to 10 mass %. When the TiO₂ content is 5 to 10 mass %, the linear expansion coefficient of the glass at around room temperature is substantially zero so that almost no dimensional change occurs at around room temperature. The SiO₂—TiO₂ glass may contain any trace component other than SiO₂ and TiO₂.

It is preferable that a surface (hereinafter also referred to as a “first main surface”) of the substrate on which the multilayer reflective film is disposed is high in surface smoothness. The surface smoothness of the first main surface can be evaluated on the basis of surface roughness. The surface roughness of the first main surface is preferably 0.15 nm or less in terms of the root mean square roughness Rq. Here, the surface roughness can be measured with an atomic force microscope, and will be described as the root mean square roughness Rq according to JIS B0601.

From the viewpoint of improving the pattern transfer accuracy and positional accuracy of a reflective mask obtained by processing a reflective mask blank obtained from the multilayer reflective film-provided substrate, the first main surface is preferably surface-processed to a predetermined level of flatness. The flatness of the substrate at a predetermined area (for example, an area of 132 mm×132 mm) of the first main surface is preferably 100 nm or less, more preferably 50 nm or less, still more preferably 30 nm or less. The flatness can be measured with a flatness measurement system manufactured by FUJINON Corporation.

The size and thickness etc. of the substrate are determined as appropriate depending on the design value of the mask and the like. For example, the substrate may be formed with an outer size of 6 inches (152 mm) square and a thickness of 0.25 inches (6.3 mm).

Further, the substrate is preferably high in rigidity to prevent deformation due to stress of the film (multilayer reflective film or the like) formed on the substrate. For example, the Young's modulus of the substrate is preferably 65 GPa or higher.

### [Multilayer Reflective Film]

The multilayer reflective film in the multilayer reflective film-provided substrate of the present invention has a structure such that low refractive index layers and high refractive index layers are alternately stacked.

The multilayer reflective film is not particularly limited as long as it reflects EUV light and it has properties required for reflective films of EUV mask blanks. It is preferable that the multilayer reflective film has a high EUV light reflectance. More specifically, when a surface of the multilayer reflective film is irradiated with EUV light at an incident angle of 6°, the maximum reflectance of EUV light with a wavelength near 13.5 nm from the multilayer reflective film is preferably 60% or higher, more preferably 65% or higher.

As described above, the multilayer reflective film has a structure such that high refractive index layers of high EUV refractive index and low refractive index layers of low EUV refractive index are alternately stacked to achieve a high EUV light reflectance.

Assuming a stacked unit in which a high refractive index layer and a low refractive index layer are stacked in this order from the substrate side as one cycle, the multilayer reflective film may have a laminated structure formed by a plurality of cycles. Assuming a stacked unit in which a low refractive index layer and a high refractive index layer are stacked in this order from the substate side as one cycle, the multilayer reflective film may have a laminated structure formed by a plurality of cycles.

The high refractive index layer can be a layer containing Si. Examples of the Si-containing material include elemental Si and a Si compound containing Si and at least one member selected from the group consisting of B, C, N and O. With the use of such Si-containing high refractive index layers, a reflective mask blank and a reflective mask, with a high EUV light reflectance, can be obtained. Each high refractive index layer may be a single layer or a multilayer.

Each high refractive index layer has a thickness of preferably 2.0 to 6.0 nm, more preferably 3.0 to 5.0 nm.

The thickness of the high refractive index layer is obtained by X-ray reflectivity (XRR). The detailed measurement conditions are as described later in Examples.

The low refractive index layer can be a layer containing a metal selected from the group consisting of Mo, Ru, Rh and Pt or an alloy thereof. The low refractive index layer is preferably a layer containing Mo. Each low refractive index layer may be a single layer or a multilayer.

In the high refractive index layer, Si is widely used. In the low refractive index layer, Mo is widely used. In other words, the most commonly used is a Mo/Si multilayer reflective film. The multilayer reflective film is however not limited to this type. Other examples of the multilayer reflective film usable include a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo multilayer reflective film and a Si/Ru/Mo/Ru multilayer reflective film.

Each low refractive index layer has a thickness of preferably 3.2 nm or more. The upper limit of the thickness of the low refractive index layer may, for example, be 5.0 nm.

The thickness of the low refractive index layer may be obtained by XRR.

In the multilayer reflective film-provided substrate of the present invention, in a diffraction chart obtained by X-ray diffraction measurement, a crystallite size calculated from a diffraction peak with the maximum intensity attributable to the low refractive index layer is more than 3.1 nm. The crystallite size is preferably 3.2 nm or more, whereby the thickness of the diffusion layer when heated is further less likely to change.

The upper limit of the crystallite size is not particularly limited, and is preferably 6.0 nm or less, more preferably 5.0 nm or less, with a view to reducing the surface roughness of the multilayer reflective film-provided substrate.

In this specification, X-ray diffraction (XRD) measurement is conducted by Out-of-plane method. That is, in a plane orthogonal to the surface of the multilayer reflective film of the multilayer reflective film-provided substrate, the X-ray incident direction and the X-ray detector disposition direction are changed. Out-of-plane method is also called 0-2θ scanning in which scanning is conducted while such a relation is satisfied that when the X-ray incident direction is θ° with the surface of the multilayer reflective film, the X-ray detector disposition direction is 2θ° with the X-ray incident angle.

The detailed XRD measurement conditions are as described later in Examples.

The crystallite size is calculated from a diffraction peak with the maximum peak attributable to the low refractive index layer from a diffraction chart obtained by XRD measurement. In this specification, for calculation of the crystallite size, Scherrer's equation is applied, the full width at half maximum of the diffraction peak is employed for calculation, and the Scherrer constant K is 0.89.

For example, in a case where the low refractive index layer contains Mo, the diffraction peak with the maximum intensity attributable to the low refractive index layer is a diffraction peak attributable to 110 reflection of Mo (appears at 2θ:39 to) 42° in many cases.

Further, it is also preferable that in a case where the low refractive index layer contains Mo, the half-width of a peak attributable to 110 reflection of Mo obtained by rocking curve measurement is 11.8° or more.

The rocking curve measurement is conducted in such a manner that only the angle of disposition of the multilayer reflective film-provided substrate is changed while angles of the X-ray incident direction and the X-ray detector disposition direction are kept, so that the peak attributable to 110 reflection of Mo has a peak top value. During the measurement, the angle of disposition of the multilayer reflective film-provided substrate is changed centering on the rotation axis of the X-ray incident direction and the X-ray detector disposition direction. The half-width of the rocking curve may be calculated from a profile of diffraction intensity change in a direction corresponding to the Debye rings azimuthal direction (Debye rings circumferential direction) using a two-dimensional detector.

As the half-width, the full width at half maximum in a curve obtained by the above measurement is employed. The half-width is more preferably 12.0° or more, further preferably 12.4° or more, whereby the thickness of the diffusion layer when heated is further less likely to change.

The upper limit of the half-width is not particularly limited, and is preferably 24° or less, more preferably 20° or less, further preferably 18° or less, whereby the roughness of the interface is less likely to increase. The roughness of the interface is considered to be caused because the crystal face is likely to be exposed to the interface by a decrease in alignment property.

In a case where the low refractive index layer contains Mo, it is also preferable that in analysis of the multilayer reflective film-provided substrate by X-ray fluorescence analysis (XRF), the ratio of the detection intensity of ArKα ray to the detection intensity of MoLα ray is 0.0010 or less.

In a case where the low refractive index layer contains Mo, it is also preferable that in analysis of the multilayer reflective film-provided substrate by XRF, the ratio of the detection intensity of AlKα ray to the detection intensity of MoLα ray is 0.0030 or less.

In analysis of the multilayer reflective film-provided substrate by XRF, the lower limit of the ratio of the detection intensity of ArKα ray to the detection intensity of MoLα ray is not particularly limited and may be 0. The lower limit of the detection intensity of AlKα ray to the detection intensity of MoLα ray is not particularly limited and may be 0.

Analysis by XRF is conducted by applying X-rays from the multilayer reflective film side of the multilayer reflective film-provided substrate. The detailed measurement conditions are as described later in Examples.

Between the high refractive index layer and the low refractive index layer, a diffusion layer may be present. The diffusion layer means a region containing elements of the material constituting the high refractive index layer and elements of the material constituting the low refractive index layer.

The ratio of the thickness of the diffusion layer to the thickness of the low refractive index layer is preferably 1.0 or less, more preferably 0.9 or less, further preferably 0.8 or less.

The lower limit of the ratio of the thickness of the diffusion layer to the thickness of the low refractive index layer is not particularly limited and may be 0.

The thickness of the diffusion layer is obtained by XRR.

The multilayer reflective film of the multilayer reflective film-provided substrate of the present invention is also preferably such that the ratio of the thickness of the low refractive index layer to the total thickness of a pair of one low refractive index layer and one high refractive index layer is 0.40 or more. The thickness ratio is more preferably 0.42 or more, further preferably 0.45 or more, whereby the thickness of the diffusion layer is further less likely to change when heated.

The upper limit of the ratio of the thickness of the low refractive index layer to the total thickness of the low refractive index layer and the high refractive index layer is not particularly limited, and with a view to increasing the reflectance, it is preferably 0.60 or less, more preferably 0.55 or less.

The pair of one low refractive index layer and one high refractive index layer means a pair of a low refractive index layer and a high refractive index layer adjacent to each other among the low refractive index layers and the high refractive index layers stacked alternately.

The thickness ratio may be calculated by the thickness of the low refractive index layer and the thickness of the high refractive index layer obtained by the above-described method. In a case where the multilayer reflective film contains the diffusion layer, the thickness ratio is obtained from the following formula (I). In the formula (I), R is the thickness ratio, d_{L} is the thickness of the low refractive index layer, d_{H} is the thickness of the high refractive index layer, and d_{D} is the thickness of the diffusion layer.

$$R = ( {d}_{L} + {d}_{D} / 2 ) / ( {d}_{L} + {d}_{H} + {d}_{D} ) \qquad formula ( I )$$

In the multilayer reflective film, the number of units each containing one low refractive index layer and one high refractive index layer (pairs of the low refractive index layer and the high refractive index layer) may properly be selected depending upon the required EUV light reflectance and is preferably 20 to 60.

The low refractive index layers and the high refractive index layers constituting the multilayer reflective film may be formed by a known method, such as magnetron sputtering method or ion beam sputtering method. It is particularly preferable that the low refractive index layers and the high refractive index layers are formed by magnetron sputtering method.

In a case were the low refractive index layer is formed by magnetron sputtering method, using materials forming the low refractive index layer as a target, sputtering is conducted while a sputtering gas (for example a rare gas such as Ne gas, Ar gas or Kr gas) is supplied. During sputtering, the sputtering gas is formed into plasma particles by applying magnetic fields and a volage, the plasma particles are collided with the target, and the materials constituting the target are deposited on the substrate or on the formed high refractive index layer.

When the low refractive index layer is formed by magnetron sputtering method, the pressure in the apparatus is preferably 1.0×10⁻³ to 1.0×10⁻¹ Pa.

When the low refractive index layer is formed by magnetron sputtering method, the electric current applied is preferably 100 to 800W, more preferably 100 to 600W, further preferably 100 to 500W.

The multilayer reflective film-provided substrate of the present invention may further have a protective film as described in the section on the reflective mask blank, on the opposite side of the multilayer reflective film from the substrate.

Further, the multilayer reflective film-provided substrate of the present invention may have an oxide film between the multilayer reflective film and the protective film. The oxide film may also be a film having the outermost layer of the multilayer reflective film on the farthest side from the substrate oxidized.

### <Reflective Mask Blank>

The multilayer reflective film-provided substrate of the present invention is to be used for a reflective mask blank, and by further having the after-described absorber film, it functions as a reflective mask blank (the reflective mask blank of the present invention).

That is, the reflective mask blank of the present invention is a reflective mask blank having a substrate, a multilayer reflective film to reflect EUV light and an absorber film in this order.

The multilayer reflective film has a structure such that the low refractive index layers and the high refractive index layers are alternately stacked, and a crystallite size calculated from a diffraction peak with the maximum intensity attributable to the low refractive index layer in X-ray diffraction measurement is more than 3.1 nm.

The reflective mask blank of the present invention will be described with reference to Drawings.

FIG. 2 is a cross sectional view illustrating an example of an embodiment of the reflective mask blank of the present invention. A reflective mask blank 20 shown in FIG. 2 has a back-side conductive film 22, a substrate 12, a multilayer reflective film 14, a protective film 6 and an absorber film 18 in this order.

The reflective mask blank 20 in FIG. 2 has the back-side conductive film 22 and the protective film 16, but it may not have the protective film 16 or the back-side conductive film 22.

The multilayer reflective film 14 satisfies the above requirements.

It is considered that in the reflective mask blank of the present invention, from the above reasons, the thickness of the diffusion layer in the multilayer reflective film is less likely to change.

Now, the configuration which the reflective mask blank of the present invention has and the configuration which the reflective mask blank of the present invention may have, will be described. The multilayer reflective film and the substrate in the reflective mask blank of the present invention are the same as the multilayer reflective film and the substate in the above-described multilayer reflective film-provided substrate of the present invention, and their description is omitted.

### [Protective Film]

The reflective mask blank of the present invention may have a protective film between the multilayer reflective film and the absorber film. The protective film is formed for the purpose of, during patterning of the absorber film by an etching process (in general, a dry etching process), protecting the multilayer reflective film from damage by the etching process.

As a material to achieve the above object, a material containing at least one element selected from the group consisting of Ru and Rh may be mentioned. That is, the protective film preferably contains at least one element selected from the group consisting of Ru and Rh.

More specifically, the material includes elemental Ru metal, a Ru alloy containing Ru and at least one element selected from the group consisting of Si, Ti, Nb, Rh and Zr, and a Rh-based material such as elemental Rh metal, a Rh alloy containing Rh and at least one metal selected from the group consisting of Si, Ti, Nb, Ru, Ta and Zr, a Rh-containing nitride containing the Rh alloy and nitrogen, and a Rh-containing oxynitride containing the Rh alloy, nitrogen and oxygen.

As the material to achieve the above object, a nitride containing Al, the above metal and nitrogen, and Al₂O₃ may also be mentioned.

Particularly, as the material to achieve the above object, elemental Ru metal, the Ru alloy, elemental Rh metal or the Rh alloy is preferred. The Ru alloy is preferably a Ru—Si alloy, and the Rh alloy is preferably a Rh—Si alloy.

The film thickness of the protective film is not particularly limited as long as the protective film performs its function. From the viewpoint of maintaining the reflectance of EUV light from the multilayer reflective film, the film thickness of the protective film is preferably 1 to 10 nm, more preferably 1.5 to 6 nm, still more preferably 2 to 5 nm.

It is also preferable that the material of the protective film is elemental Ru metal, the Ru alloy, elemental Rh metal or the Rh alloy and that the protective film has the above preferred film thickness.

The protective film may be a single layer film or a multilayer film. In a case where the protective film is a multilayer film, the respective layers constituting the multilayer film are formed preferably by the above preferred materials. Further, in a case where the protective film is a multilayer film, the total film thickness of the multilayer film is preferably the above preferred film thickness of the protective film.

The protective film can be formed by a known film formation method such as a magnetron sputtering method, an ion beam sputtering method or the like. In the case where a Ru film is formed by magnetron sputtering, the sputtering is preferably performed using a Ru target as the target and Ar gas as the sputtering gas.

### [Absorber Film]

The absorber film in the reflective mask blank of the present invention is required to, during patterning of the absorber film, generate a high contrast between EUV light reflected by the multilayer reflective film and EUV light reflected by the absorber film.

The patterned absorber film (absorber film pattern) may serve as a binary mask to absorb EUV light, or may serve as a phase shift mask to reflect EUV light and generate a contrast by interference of the reflected light with EUV light from the multilayer reflective film.

In the case where the absorber film pattern is used as a binary mask, the absorber film needs to absorb EUV light and show a low EUV light reflectance. More specifically, when a surface of the absorber film is irradiated with EUV light, the maximum reflectance of EUV light with a wavelength near 13.5 nm from the absorber film is preferably 2% or lower.

The absorber film may contain, in addition to at least one metal selected from the group consisting of Ta, Ti, Sn and Cr, at least one element selected form the group consisting of O, N, B, Hf and H. Among others, the absorber film preferably contains N or B. By containing N or B, the crystalline state of the absorber film can be made amorphous or microcrystalline.

The crystalline state of the absorber film is preferably amorphous. This leads to improved smoothness and flatness of the absorber film. When the smoothness and flatness of the absorber film are improved, the absorber film pattern can be reduced in edge roughness and improved in dimensional accuracy.

In the case where the absorber film pattern is used as a binary mask, the film thickness of the absorber film is preferably 40 to 70 nm, more preferably 50 to 65 nm.

In the case where the absorber film pattern is used as a phase shift mask, the reflectance of EUV light from the absorber film is preferably 2% or higher. In order to obtain a sufficient phase shift effect, the reflectance of EUV light from the absorber film is more preferably 9 to 15%. The use of the absorber film as a phase shift mask leads to an improved optical image contrast on a wafer and an increase of exposure margin.

Examples of the material for forming the phase shift mask include elemental Ru metal, a Ru alloy containing Ru and at least one metal selected from the group consisting of Cr, Au, Pt, Re, Hf, Ta, Ti and Si, an alloy of Ta and Nb, an oxide containing a Ru alloy or a TaNb alloy and oxygen, a nitride containing a Ru alloy or a TaNb alloy and nitrogen, an oxynitride containing a Ru alloy or a TaNb alloy, oxygen and nitrogen, for example, a compound containing at least one noble metal element selected from the group consisting of Ir, Pt, Pd, Ag and Au. In a case where the absorber film pattern is used as the phase shift mask, the film thickness of the absorber film is preferably 30 to 60 nm, more preferably 35 to 55 nm.

The absorber film may be a single-layer film or a multilayer film constituted by a plurality of film layers. In the case where the absorber film is a single-layer film, the number of process steps in the production of the mask blank can be reduced to obtain an improvement of production efficiency. In the case where the absorber film is a multilayer film, the layer of the absorber film opposite to the multilayer reflective film protective film may be an anti-reflective film for inspection of the absorber film pattern by irradiation with inspection light (e.g. light with a wavelength of 193 to 248 nm).

The absorber film can be formed by a known film formation method such as a magnetron sputtering method, an ion beam sputtering method or the like. For example, in the case where a Ru oxide film is formed as the absorber film by magnetron sputtering, the absorber film can be formed by performing the sputtering using a Ru target with the supply of a gas containing Ar gas and oxygen gas.

### [Back-Side Conductive Film]

The reflective mask blank of the present invention may have a back-side conductive film formed on a surface (second main surface) of the substrate opposite to the first main surface. The formation of the back-side conductive film enables handling of the reflective mask blank by electrostatic chuck.

It is preferable that the back-side conductive film has a low sheet resistance. The sheet resistance of the back-side conductive film is, for example, preferably 200 Ω/sq. or lower, more preferably 100/sq. or lower.

The material of the back-side conductive film can be widely selected from those described in publicly known literature. For example, a high dielectric constant coating as disclosed in JP-A-2003-501823, such as a coating of Si, Mo, Cr, CrON or TaSi, is applicable. The material of the back-side conductive film may be a Cr compound containing Cr and at least one selected from the group consisting of B, N, O and C, or a Ta compound containing Ta and at least one selected from the group consisting of B, N, O and C.

The film thickness of the back-side conductive film is preferably 10 to 1000 nm, more preferably 10 to 400 nm.

Furthermore, the back-side conductive film may have the function of adjusting stress on the second main surface side of the reflective mask blank. In other words, the back-side conductive film may function to keep the reflective mask blank flat by balancing with stress from the respective films formed on the first main surface side.

The back-side conductive film can be formed by a known film formation method such as a sputtering method e.g. a magnetron sputtering method or an ion beam sputtering method, a CVD method, a vacuum deposition method or an electrolytic plating method.

### [Other Film]

The reflective mask blank of the present invention may have other film. Such other film may be a hard mask film. The hard mask film is disposed preferably on the opposite side of the absorber film from the substrate.

The hard mask film is preferably a film of a material with high resistance to dry etching, such as a Cr-based film or a Si-based film. The Cr-based film may, for example, be a film of Cr, or a material containing Cr and at least one element selected from the group consisting of O, N, C and H. Specifically, CrO and CrN may, for example, be mentioned. The Si-based film may be e.g. a film of Si, or a material containing Si and at least one member selected from the group consisting of O, N, C and H. Specifically, SiO₂, SiON, SiN, SiO, Si, SiC, SiCO, SiCN and SiCON may, for example, be mentioned. By forming the hard mask film on the absorber film, dry etching can be conducted even if the minimum line width of the absorber film is small. Thus, the hard mask film is effective for miniaturization of the absorber film pattern.

### <Method for Producing Reflective Mask, and Reflective Mask>

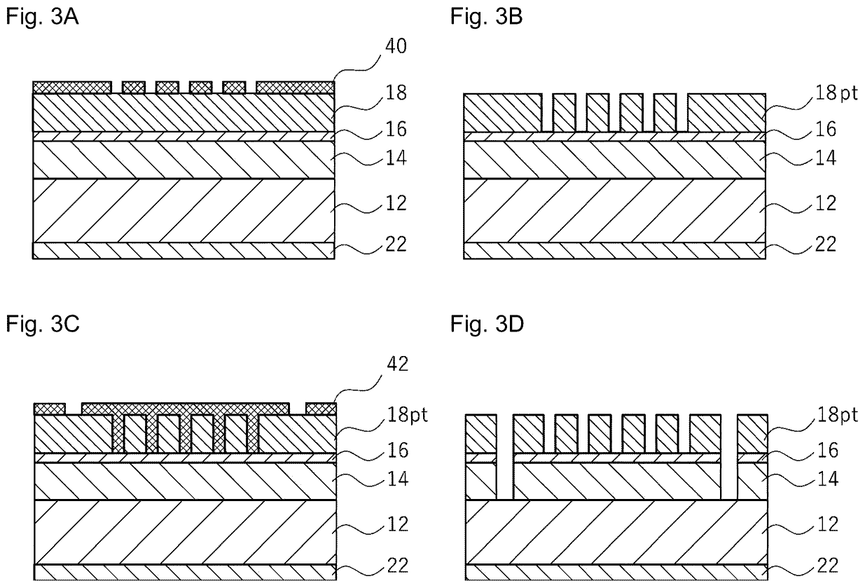

The reflective mask can be produced by patterning the absorber film of the reflective mask blank. An example of the method for producing the reflective mask will be described below with reference to FIGS. 3A-3D.

In FIG. 3A, shown is a state that a resist pattern 40 is formed on the reflective mask blank in which the back-side conductive film 22, the substrate 12, the multilayer reflective film 14, the protective film 16 and the absorber film 18 have been stacked in this order. The resist pattern 40 can be formed by a known method. For example, the resist pattern 40 is formed by applying a resist to the absorber film 18 of the reflective mask blank and subjecting the applied resist to exposure and development. Here, the resist pattern 40 corresponds to a pattern to be formed on a wafer via the reflective mask.

Next, using the resist pattern 40 shown in FIG. 3A as a mask, the absorber film 18 is etched and patterned, and the resist pattern 40 is removed to obtain the laminate with an absorber film pattern 18 pt as shown in FIG. 3B.

As shown in FIG. 3C, a resist pattern 42 is then formed on the laminate shown in FIG. 3B in a shape corresponding to the frame of the exposure region. Dry etching is performed using the resist pattern 42 shown in FIG. 3C as a mask. This dry etching is performed until reaching the substrate 12. After the dry etching, the resist pattern 42 is removed to obtain the reflective mask as shown in FIG. 3D.

The dry etching for formation of the absorber film pattern 18 pt, for example, dry etching with Cl-based gas or dry etching with F-based gas may be mentioned.

Removal of the resist pattern 40 or 42 may be conducted by a known method, such as removal by a cleaning liquid. The cleaning liquid may, for example, be sulfuric acid/hydrogen peroxide aqueous solution (SPM), sulfuric acid, aqueous ammonia, ammonia/hydrogen peroxide aqueous solution (APM), OH radical cleaning water or ozone water.

The reflective mask obtained by patterning the absorber film of the reflective mask blank of the present invention is suitably usable as a reflective mask for EUV light exposure.

The reflective mask may be heated at the time of EUV exposure, however, in the reflective mask of the present invention, the thickness of the diffusion layer present in the multilayer reflective film when heated is less likely to change.

### EXAMPLES

Now, the present invention will be described in further detail with reference to Examples.

The materials, amounts used, proportions, processing operations, processing procedures and the like shown in the following Examples can be changed as appropriate without departing from the spirit and scope of the present invention. The present invention is therefore by no means restricted to the following Examples. Here, Ex. 1 corresponds to an Example of the present invention; and Ex. 2 to 4 correspond to Comparative Examples.

### <Ex. 1>

First, a procedure for obtaining a multilayer reflective film-provided substrate of Ex. 1 will be representatively described below.

### [Substrate]

As a substrate, a substrate of SiO₂—TiO₂ glass (outer size: 6 inches (152 mm) square, thickness: 6.3 mm) was provided. This glass substrate had a thermal expansion coefficient of 0.02×10⁻⁷/° C. at 20° C., a Young's modulus of 67 GPa, a Poisson's ratio of 0.17 and a specific stiffness of 3.07×10⁷ m²/s². A quality assurance area on a first main surface of the substrate was formed with a root mean square roughness (Rq) of 0.15 nm or less and a flatness of 100 nm or less by polishing.

### [Multilayer Reflective Film]

Next, a Mo/Si multilayer reflective film was formed as a multilayer reflective film on the first main surface of the substrate. The Mo/Si multilayer film was obtained by repeating the formation of a Si layer (thickness: 3.8 nm) and a Mo layer (thickness: 3.2 nm) by magnetron sputtering 40 times and, after the formation of the 40th Mo layer, further forming a Si layer (thickness: 4.0 nm). The thickness of each layer is the film thickness as calculated from the sputtering rate and the sputtering time. The sputtering rate can be obtained by a film thickness monitor attached to an apparatus for conducting magnetron sputtering.

In magnetron sputtering, Ar gas was supplied to adjust the gas pressure at the time of sputtering to be 0.05 Pa. The amount of the Ar gas supplied was 25 sccm. “sccm” is a unit representing the gas flow rate (mL/min) under standard conditions.

In Ex. 1, the sputtering conditions for each film were as follows.
(Si layer) electric power charged: 1000W
(Mo layer) electric power charged: 500W

### [Protective Film]

After the multilayer reflective film was formed by the above procedure, a Ru layer (protective film) was formed on the opposite side of the multilayer reflective film from the substrate.

The Ru layer was formed by magnetron sputtering with an applied electric power of 500W to a film thickness of 2.5 nm. The gas pressure was the same as for formation of the multilayer reflective film.

By the above procedure, the multilayer reflective film-provided substrate in Ex. 1 was obtained.

In the following, Ex. 2 to 4 will be described focusing only on the differences from the procedure for obtaining the multilayer reflective film-provided substrate of Ex. 1.

### <Ex. 2>

A multilayer reflective film-provided substrate of Ex. 2 was obtained by the same procedure as in Ex. 1 except that electric power applied at the time of sputtering for the Mo layer was changed to 600W.

### <Ex. 3>

A multilayer reflective film-provided substrate of Ex. 3 was obtained by the same procedure as in Ex. 1 except that electric power applied at the time of sputtering for the Mo layer was changed to 800W.

### <Ex. 4>

A multilayer reflective film-provided substrate of Ex. 4 was obtained by the same procedure as in Ex. 1 except that electric power applied at the time of sputtering for the Mo layer was changed to 900W.

### <Measurement Method>

### [Crystallite Size]

The crystallite size of the low refractive index layer (Mo layer) in the multilayer reflective film-provided substrate of each Ex. was calculated from a diffraction peak with the maximum intensity attributable to the low refractive index layer from a diffraction chart obtained by XRD measurement. The calculation method is as described above. The multilayer reflective film-provided substrate of each Ex. was subjected to the XRD measurement and as a result, a peak attributable to 110 reflection of Mo was observed.

In the XRD measurement, “D8 DISCOVER Plus” manufactured by Bruker was used. The X-ray source was CuKα rays (including CuKα₁ ray and CuKα₂ ray), the tube voltage was 45 kV, and the tube current was 120 mA. For the measurement, a two-dimensional detector was used.

A microslit of 1.0 mm in diameter and a collimator of 1.0 mm in diameter were used on the X ray source side. The step width was 0.02°, and the step time was 0.2 s/step, and measurement was conducted at 20 within a range of 20 to 80°.

### [Rocking Curve]

Using the above apparatus, rocking curve measurement was conducted with respect to the diffraction peak of 110 reflection of Mo.

### [Film Thickness]

The thicknesses of the low refractive index layer and the high refractive index layer were obtained by XRR. The XRR measurement apparatus was the same as the apparatus for the XRD measurement. The measurement conditions were partly changed as follows.

The X ray source was CuKα rays (including CuKα₁ ray and CuKα₂ ray), the tube voltage was 45 kV, and the tube current was 120 mA. For measurement, a two-dimensional detector was used. A 0.05 mm slit and a 4.1° solar slit were used on the X ray source side, and a 4° solar slit and a double crystal analyzer were used on the detector side. Measurement was conducted within a range of 0 to 9° with a step width of 0.005°.

XRR fitting was conducted assuming that the layer structure was (Si layer/diffusion layer/Mo layer/diffusion layer)×40/Si layer/RuSi diffusion layer/Ru layer from the substrate side.

From the film thicknesses of the low refractive index layer and the high refractive index layer obtained by the above procedure and the film thickness of the diffusion layer, the value of R obtained from the formula (I) was calculated, and is described as “γ ratio” in the after-described Table.

### [XRF Intensity Ratio]

With respect to the multilayer reflective film-provided substrate obtained in each Ex., XRF measurement was conducted and the ratio of the detection intensity of ArKα ray to the detection intensity of MoLα ray (“Ar/Mo” in Tables), and the ratio of the detection intensity of AlKα ray to the detection intensity of MoLα ray (“Al/Mo” in Table) were calculated.

XRF measurement was conducted by “ZSX Primus II” manufactured by Rigaku Corporation.

### <Evaluation Method>

Heat resistance of the multilayer reflective film-provided substrate (change of thickness of the diffusion layer when heated) in each Ex. was evaluated in the following procedure.

First, the multilayer reflective film-provided substrate obtained in each Ex. was put in a vacuum furnace and heated at 180° C. for 30 minutes.

After heating, XRR measurement was conducted in the same procedure as above and the thickness of the diffusion layer after heating was calculated, thereby to calculate an increase of the thickness of the diffusion layer as compared with that before heating. The results are shown in the following Table.

### <Results>

The measurement results and the evaluation results of the multilayer reflective film-provided substrate of each Ex. are shown in Table.

TABLE 1

| | XRD | | | | | Evaluation |
|---|---|---|---|---|---|---|
| | Crystallite | | | | | Change in |
| | size [nm] of | Rocking | | | | thickness of |
| Table | low refractive | curve half- | XRF | | XRR | diffusion layer |
| 1 | index layer | width [°] | Ar/Mo | Al/Mo | γ Ratio | after heating [nm] |
| Ex. 1 | 3.2 | 12.6 | 0.0006 | 0.0004 | 0.452 | 0.017 |
| Ex. 2 | 3.0 | 12.4 | 0.0004 | 0.0006 | 0.424 | 0.022 |
| Ex. 3 | 2.6 | 11.9 | 0.0008 | 0.0007 | 0.401 | 0.025 |
| Ex. 4 | 2.3 | 11.6 | 0.0018 | 0.0037 | 0.390 | 0.056 |

As evident from the results shown in Table, it was confirmed that a crystallite size calculated from a diffraction peak with the maximum intensity attributable to the low refractive index layer of more than 3.1 nm leads to a less change of the diffusion layer when heated.

By forming an absorber layer on the opposite side of the protective film of the multilayer reflective film-provided substrate obtained by the above procedure, from the multilayer reflective film, a reflective mask blank is obtained.

This application is a continuation of PCT Application No. PCT/JP2024/027152, filed on Jul. 30, 2024, which is based upon and claims the benefit of priority from Japanese Patent Application No. 2023-132506 filed on Aug. 16, 2023. The contents of those applications are incorporated herein by reference in their entireties.

### REFERENCE SYMBOLS

10: multilayer reflective film-provided substrate
12: substrate
14: multilayer reflective film
16: protective film
18: absorber film
18pt: absorber film pattern
20: reflective mask blank
22: back-side conductive film
40, 42: resist pattern

What is claimed is:

1. A multilayer reflective film-provided substrate for reflective mask blank, comprising:
a substrate, and
a multilayer reflective film to reflect EUV light,
wherein
the multilayer reflective film has a structure such that low refractive index layers and high refractive index layers are alternately stacked, and
in a diffraction chart obtained by X-ray diffraction measurement, a crystallite size calculated from a diffraction peak with the maximum intensity attributable to the low refractive index layers is more than 3.1 nm.

2. The multilayer reflective film-provided substrate according to claim 1, wherein
the low refractive index layers contain molybdenum, and
the high refractive index layers contain silicon.

3. The multilayer reflective film-provided substrate according to claim 2, wherein in X-ray fluorescence analysis, a ratio of a detection intensity of Arka ray to a detection intensity of MoLα ray is 0.0010 or less.

4. The multilayer reflective film-provided substrate according to claim 2, wherein in X-ray fluorescence analysis, a ratio of a detection intensity of AlKα ray to a detection intensity of MoLα ray is 0.0030 or less.

5. The multilayer reflective film-provided substrate according to claim 2, wherein in rocking curve measurement with respect to a peak attributable to 110 reflection of molybdenum in the low refractive index layers, a half-width is 11.8° or more.

6. The multilayer reflective film-provided substrate according to claim 1, wherein, to a total thickness of a pair of one low refractive index layer and one high refractive index layer, a ratio of a thickness of the low refractive index layer is 0.40 or more.

7. A method for producing the multilayer reflective film-provided substrate as defined in claim 1, which comprises:
forming the low refractive index layers and the high refractive index layers by magnetron sputtering method.

8. A reflective mask blank, comprising, in order:
a substrate,
a multilayer reflective film to reflect EUV light, and
an absorber film,
wherein
the multilayer reflective film has a structure such that low refractive index layers and high refractive index layers are alternately stacked, and
in X-ray diffraction measurement, a crystallite size calculated from a diffraction peak with a maximum intensity attributable to the low refractive index layers is more than 3.1 nm.

9. The reflective mask blank according to claim 8, wherein
the low refractive index layers contain molybdenum, and
the high refractive index layers contain silicon.

10. The reflective mask blank according to claim 9, wherein in X-ray fluorescence analysis, a ratio of a detection intensity of ArKα ray to a detection intensity of MoLα ray is 0.0010 or less.

11. The reflective mask blank according to claim 9, wherein in X-ray fluorescence analysis, a ratio of a detection intensity of AlKα ray to a detection intensity of MoLα ray is 0.0030 or less.

12. The reflective mask blank according to claim 9, wherein in rocking curve measurement with respect to a peak attributable to 110 reflection of molybdenum in the low refractive index layers, a half-width is 11.8° or more.

13. The reflective mask blank according to claim 8, wherein, to a total thickness of a pair of one low refractive index layer and one high refractive index layer, a ratio of a thickness of the low refractive index layer is 0.40 or more.

14. A reflective mask having a phase shift film pattern formed by patterning the absorber film of the reflective mask blank as defined in claim 8.

15. A method for producing a reflective mask, which comprises a step of patterning the absorber film in the reflective mask blank as defined in claim 8.
